(19) United States
(12) Patent Application Publication
(10) Pub. No.: US 2009/0242929 A1
(43) Pub. Date: Oct. 1, 2009

(54) LIGHT EMITTING DIODES WITH PATTERNED CURRENT BLOCKING METAL CONTACT

(76) Inventor: Chao-Kun LIN, Sunnyvale, CA (US)

Correspondence Address: Arent Fox LLP, 555 West Fifth Street, 48th Floor, Los Angeles, CA, 90013, US

(21) Appl. No.: 12/113,556

(22) Filed: May 1, 2008

Related U.S. Application Data
(60) Provisional application No. 61/041,180, filed on Mar. 31, 2008.

(51) Int. Cl. H01L 33/00; H01L 21/00

(52) U.S. Cl. 257/103; 438/46; 257/E33.001; 257/E21.001

(57) ABSTRACT

A light emitting diode including an epitaxial layer structure, a first electrode formed on the epitaxial layer structure, and a second electrode formed on the epitaxial layer structure. The first electrode has a pattern and the second electrode has a portion aligned with the pattern of the first electrode. The portion of the second electrode forms a non-ohmic contact with the epitaxial layer structure.

### CROSS-REFERENCE TO RELATED APPLICATION

The present application for patent claims priority under 35 U.S.C. §119 to Provisional Application No. 61/041,180 entitled, “Thin Film Light Emitting Diodes with Patterned Current Blocking Metal Contact,” filed Mar. 31, 2008.

### BACKGROUND

1. Field

The present disclosure relates generally to a light emitting diode, and more particularly, to a light emitting diode having current blocks.

2. Background

Light emitting diodes (LEDs) have been developed for many years and have been widely used in various light applications. As LEDs are light-weight, consume less energy, and have a good electrical power to light conversion efficiency, they have been used to replace conventional light sources, such as incandescent lamps and fluorescent light sources. The LEDs, however, produce light in a relatively narrow spectral band and have obstacles of emitting light in an efficient way because of their structural constraints. To successfully replace the conventional light sources, however, LEDs must emit as much light as possible.

Therefore, there is a need in the art to improve the structure of the LEDs so that they emit light in the most efficient way possible.

### SUMMARY

In an aspect of the disclosure, a light emitting diode includes an epitaxial layer structure, a first electrode formed on the epitaxial layer structure, the first electrode having a pattern, and a second electrode formed on the epitaxial layer structure, the second electrode having a portion aligned with the pattern of the first electrode, wherein the portion of the second electrode forms a non-ohmic contact with the epitaxial layer structure.

In another aspect of the disclosure, a method for manufacturing a light emitting diode includes forming an epitaxial layer structure, forming a first electrode, the first electrode having a first pattern on the epitaxial layer structure, and forming a second electrode on the epitaxial layer structure, wherein the second electrode is formed with a portion aligned with the pattern of the first electrode, the portion of the second electrode forming a non-ohmic contact with the epitaxial layer structure.

It is understood that other aspects of the present invention will become readily apparent to those skilled in the art from the following detailed description, wherein it is shown and described only exemplary aspects of the invention by way of illustration. As will be realized, the invention includes other and different aspects and its several details are capable of modification in various other respects, all without departing from the spirit and scope of the present invention. Accordingly, the drawings and detailed description are to be regarded as illustrative in nature and not as restrictive.

### BRIEF DESCRIPTION OF THE FIGURES

Various aspects of the present invention are illustrated by way of example, and not by way of limitation, in the accompanying drawings, wherein:

FIG. 1A is cross sectional view of a vertical LED structure.

FIG. 1B is a top view of a vertical LED structure, in which a patterned n contact is shown.

FIG. 2A is cross sectional view of a lateral LED structure.

FIG. 2B is a top view of a lateral LED structure.

FIG. 3 is a diagram showing a current density distribution of a vertical LED without current block.

FIGS. 4A-4E illustrate a process flow for manufacturing a vertical LED with a metallic current block.

FIGS. 5A-5F illustrate a process follow for manufacturing a vertical LED with a metallic current block.

FIG. 6 is a diagram showing a current density distribution of a vertical LED with current block.

### DETAILED DESCRIPTION

The detailed description set forth below in connection with the appended drawings is intended as a description of various aspects of the present invention and is not intended to represent all aspects in which the present invention may be practiced. The detailed description includes specific details for the purpose of providing a thorough understanding of the present invention. However, it will be apparent to those skilled in the art that the present invention may be practiced without these specific details. In some instances, well-known structures and components are shown in block diagram form in order to avoid obscuring the concepts of the present invention.

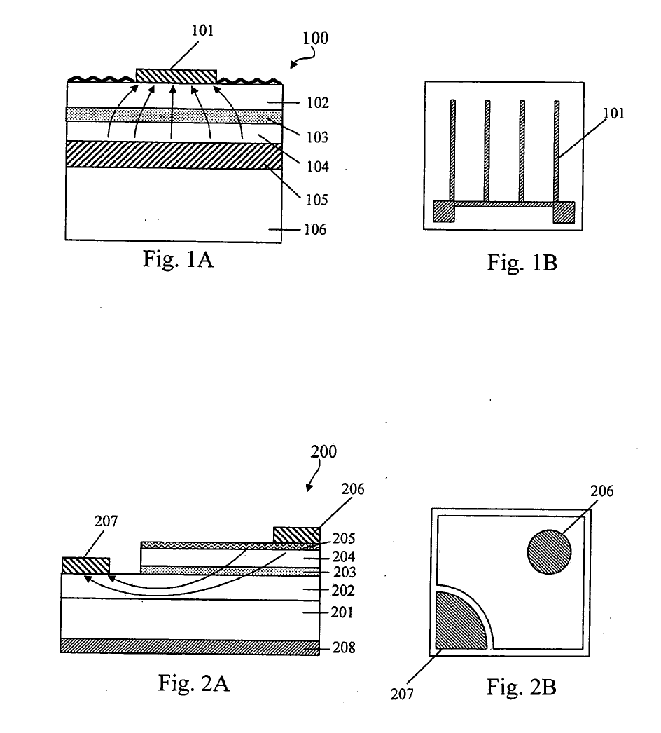

Generally, AlInGaN-based light emitting diodes (LEDs) include at least two types of LEDs: vertical LEDs and lateral LEDs. A vertical LED device 100, as shown in FIG. 1A, has a vertically current injection configuration including a patterned n-type contact (or n-type electrode) 101, an n-type GaN-based layer 102 with a roughened surface, an active region 103, a p-type GaN-based layer 104, a broad area reflective p-type contact (or p-type electrode or reflective p electrode) 105, and a thermally and/or electrically conductive substrate 106 to support the device structure mechanically. The n-type GaN-based layer 102 is formed on a temporary substrate (not shown) and the active region 103 is formed between the n-type GaN-based layer 102 and p-type GaN-based layer 104. The p-type electrode 105 is directly or indirectly formed on the p-type GaN-based layer 104. The temporary substrate on which the n-type GaN-based layer 102 is formed is removed so that the patterned n-type electrode 101 can be formed on the surface of the n-type GaN-based layer 102 that was attached to the removed substrate. FIG. 1B shows a top view of a vertical LED, in which an n-type contact with multiple electrodes is shown. It will be recognized by those of ordinary skill in the art that the pattern of the n-type contact is not limited to that shown in FIG. 1B. The reflective p-type electrode 105 is attached to the thermally conductive substrate 106 for mechanical support. As the n-type GaN-based layer 102 and the p-type GaN-based layer 104 are opposite to each other, together they form a carrier injector relative to the active region 103. Therefore, when power supply is provided to the LED device 100, electrons and holes that are injected from the p-type contact 105 and the n-type contact 101 to the active region 103 will be recombined in the active region 103, thereby releasing energy in a form of light. In FIG. 1A, arrows shown by the LED device 100 indicate an electrical path is vertically formed from the p-type electrode 105 to the patterned n-type electrode 101.

A lateral LED device 200, as shown in FIGS. 2A and 2B, has a lateral current injection configuration including a substrate, such as a sapphire substrate 201, an n-type GaN-based layer 202 formed on the substrate 201, an active region 203 formed on the n-type GaN-based layer 202, a p-type GaN-based layer 204, a TCL layer (transparent ohmic contact layer) 205, a patterned p-type electrode 206, and a patterned n-type electrode 207. As shown in FIG. 2A, parts of the active region 203, the p-type GaN-based layer 204, and the TCL 205 on the top of the n-type GaN-based layer 202 are removed to allow the n-type electrode 207 to be formed on top of the n-type GaN-based layer 202. In FIG. 2A, the arrows shown by the LED device 200 indicate an electrical path is formed laterally from the p-type electrode 206 to the patterned n-type electrode 207.

Unlike the vertical LED device, the substrate 201 of the lateral LED device remains attached to the n-type GaN-based layer and a reflector 208 is formed on a bottom side of the substrate 201. Due to the fundamental change of current flow scheme (as shown by arrows in FIGS. 1A and 2A), and the removal of the substrate from the LEDs in the vertical LED, the vertical LED device has the advantages of having a lower forward voltage (Vf) and a higher light output (LOP) in comparison with the lateral LED device.

Typically, the n-type contact of the vertical LED device may be directly placed on the n-type GaN-based layer and most of the current injection happens below the n-type contact area when a bias voltage is applied to a LED device because the least resistive path for the current flow is right below the n-type contact.

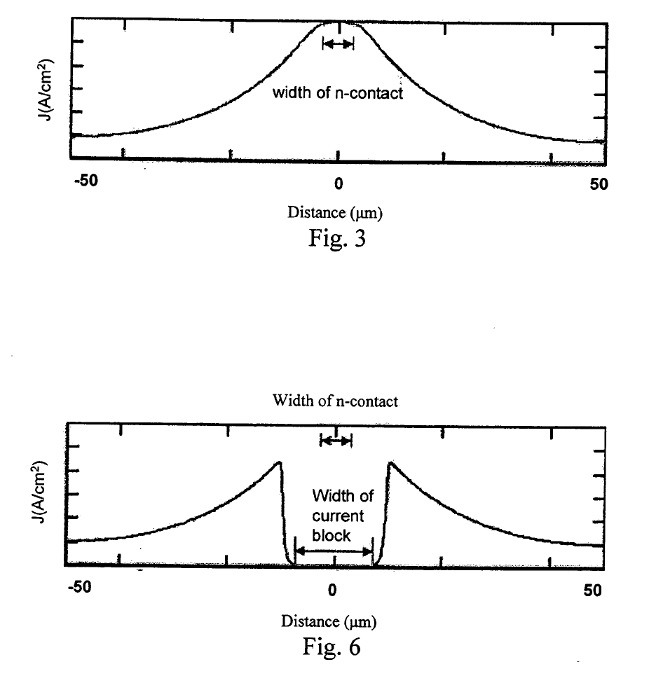

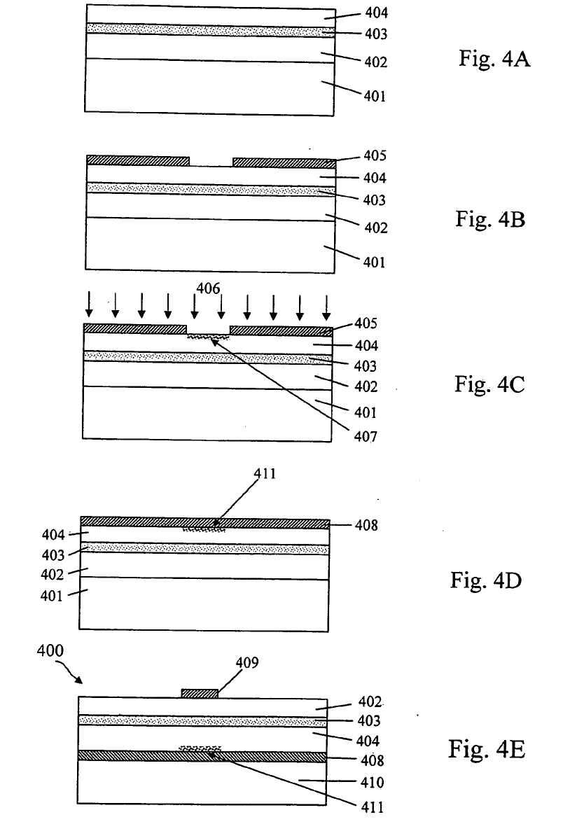

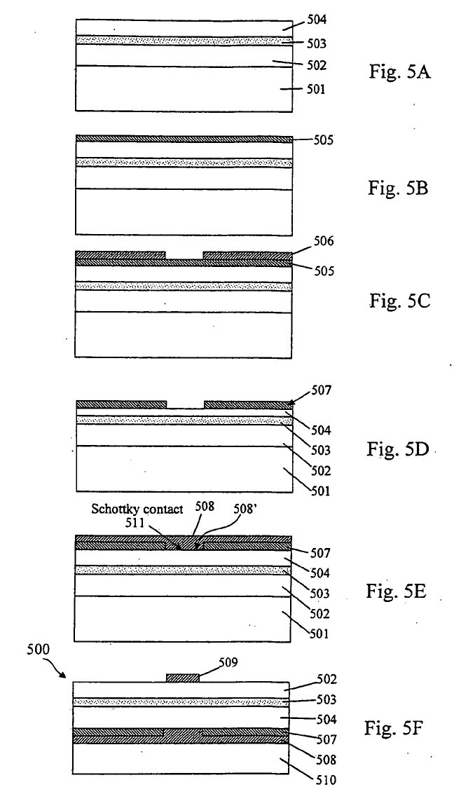

FIG. 3 shows a simulated current density distribution curve of a vertical LED device that is simulated by a finite-element-method (FEM) model. As shown in FIG. 3, the current density underneath the n-type contact is about six times the current density at the edge of the device. That is, the light generated by the current injection under the n-type contact tends to be blocked by the n-type contact and has very little chance of escaping from the LED device. Therefore, the current injected under the n-type contact is wasted and the electrical power to light conversion efficiency suffers.

To prevent the injected current from being wasted underneath the n-type contact, a current blocking region is introduced that corresponds to the pattern of the n-type contact and has a high contact voltage, such as a Schottky contact, to the p-type electrode.

In an embodiment, a vertical LED device is provided, in which electrical properties of some portion of the p-type GaN-based layer is modified prior to the deposition of a p-type contact layer, so that the contact voltage of the p-type electrode to the p-type contact layer at the modified area is greater than that of the unmodified area and a current block can be formed with a uniform planarity. The process of forming the current block will not affect the rest of manufacturing process of the vertical LED device. Furthermore, there is no change on the reflectivity of the p-type electrode at the area with modified p-type GaN-based layer, when compared to the area with unmodified p-type GaN-based layer. One example of a vertical LED device is a thin-film LED device.

FIGS. 4A-4E illustrate a vertical LED structure 400 (see FIG. 4E), and a manufacturing process thereof. Like a conventional LED, in FIG. 4A, an n-type epitaxial layer 402, an active region 403, and a p-type epitaxial layer 404 are sequentially deposited on a top surface of a substrate 401. The n-type and p-type epitaxial layers 402 and 404 may be GaN based layers. Furthermore, the substrate 401 can be sapphire (Al₂O₃) or silicon carbide (SiC).

In an embodiment, before depositing a reflective p-type electrode layer 408 (see FIG. 4D), the p-type GaN-based layer 404 is spatially modified. As illustrated in FIG. 4B, a photoresist layer 405 that has a pattern matching a patterned n-type electrode layer 409, which will be formed as shown in FIG. 4E, is used to mask the p-type GaN-based layer 404. As shown in FIG. 4C, a plasma treatment 406 is then carried out on the masked p-type GaN-based layer 404 so that a p-type doping level of the p-type GaN-based layer 404 on areas without the photoresist layer 405 is either compensated or converted into an n-type doping 407. The compensation or conversion of the p-type doing level of the p-type GaN-based layer 404 is resulted from the ion bombardment during the plasma treatment. The ion bombardment from the plasma treatment affects most at the p-type GaN-based layer surface and the material within few hundred to a thousand Å below the surface. The areas where the n-doping is compensated or converted to n-doping will not form ohmic contact and will have a high contact voltage compared to the un-treated area, thus form current block 411 embedded in a p-type electrode layer 408, which will be formed later in FIG. 4D. In one example, the plasma treatment uses gases including O₂, N₂, H₂, Ar, He, Ne, Kr, Xe, etc. or their mixture. In the following description, the current block 411 that is formed by the p-type electrode 408 deposited on the plasma treated area 407 is also called a metallic current block 407.

Next, in FIG. 4D, the photoresist layer 405 is removed and a p-type electrode layer 408 is deposited on top of the p-type GaN-based layer 404. Although FIG. 4D shows that the p-type electrode layer 408 is directly deposited on top of the p-type GaN-based layer 404, the p-type electrode layer 408 can also be indirectly deposited on the p-type GaN-based layer 404 with a transparent ohmic contact layer (not shown) formed therebetween. In either case, due to the plasma treatment performed in FIG. 4C, the p-type electrode layer 408 forms non-ohmic contacts with the plasma treated area 407. That is, on the plasma treated area 407, the p-type electrode 408 forms Schottky contact with the p-type GaN-based layer 404.

In FIG. 4E, the substrate 401 is removed and the p-type electrode layer 404 is sub-mounted on a thermally and/or electrically conductive substrate 410. The substrate 410 is intended to provide a mechanical support for the LED device 400. A patterned n-type electrode 409 is then deposited on a surface of the n-type GaN-based layer 402 that was attached with the substrate 401. As described above, the metallic current block 411 has a pattern matching with the patterned n-type electrode 409 and forms non-ohmic contact with the p-type GaN-based layer 404. Therefore, when a voltage is applied to the LED device 400, it is less likely that a current is flowing underneath the n-type electrode 409 because the-non-ohmic contact 411 is formed underneath the n-type electrode 409. In other words, less current will be wasted in the area under the n-type electrode 409, resulting in a higher electrical power to light conversion efficiency of the LED device 400.

For better light emitting efficiency, the width of the pattern of the metallic blocks 411 may be substantially equal or greater than the width of the patterned n-type electrode 409. The p-type electrode layer 408 may be formed by depositing materials such as Ag, Pt, Ni, Cr, Ti, Al, Cu, Pd, W, Ru, Rh, Mo, and/or their alloys. The p-type contact layer 408 undergoes a thermal annealing process and form ohmic contact to the p-type GaN-based layer except at the plasma treated area. Furthermore, in one example, the sub-mount substrate 410 may be formed by one of metals such as Cu, Mo, W, and Al, or their alloys, semiconductor materials such as Si, GaAs, GaP, InP, and Ge, and ceramics including Al₂O₃ and AlN.

FIGS. 5A-5F illustrate a vertical LED device 500 (see FIG. 5F), and a process for manufacturing same. Similar to FIG. 4A, before forming a metallic current block, a p-type GaN-based layer 504, an active region 503, an n-type GaN-based layer 502 are formed on a substrate 501, as shown in FIG. 5A.

As shown in FIG. 5B, a p-type electrode layer 505 is deposited on the p-type GaN-based layer 504. As described above in conjunction with FIG. 4D, prior to the deposition of the p-type electrode layer SOS, a transparent ohmic contact layer (not shown) may also be formed on the p-type GaN-based layer.

As shown FIG. 5C, a photoresist 506 having a pattern with a polarity opposite to and substantially matching a patterned n-type electrode 509, which is formed as shown in FIG. 5F, is covered on the p-type electrode layer 505. In an aspect, an etching process is then performed on the masked p-type electrode layer 505 to remove portions of the p-type electrode layer that are unmasked by the photoresist 506, and to form a patterned p-type electrode 507, as shown in FIG. 5D. As the pattern of the photoresist 506 matches with the patterned n-type electrode 509, the patterned p-type electrode 507 compliments the patterned n-type electrode 509. The p-type electrode 507 undergoes a thermal annealing process and forms an ohmic contact with the p-type GaN-based layer 504.

In FIG. 5E, a metallic current blocking layer 508 is deposited on top of the patterned p-typed electrode 507. In one example, the metallic current blocking layer is formed by depositing metals, such as Ag, Pt, Ni, Cr, Ti, Al, Cu, Pd, W, Ru, Rh, and Mo, and their metal alloys. Without undergoing the ohmic contact forming process, the metallic current blocking layer 508 forms a non-ohmic contact, i.e., Schottky contact 511, at areas of the p-type GaN-based layer without being covered by the ohmic contact 507. These areas form metallic current blocks 508′.

Next, in FIG. 5F, the substrate 501 is removed from the n-type GaN-based layer 502, and the metallic current blocking layer 508 is sub-mounted on a thermally and/or electrically conductive substrate 510 for a mechanical support. Finally, a patterned n-type electrode layer is formed on the surface of the n-type GaN-based layer 502 which was attached to the removed substrate 501.

Similar to the vertical LED device 400 as the metallic current block 508′ is formed beneath the patterned n-type electrode 509, when a voltage is applied to the vertical LED 500, it is less likely that a current is flowing underneath the n-type electrode 509 because the non-ohmic contact is formed underneath the n-type electrode 509. That is, less current will be wasted in the area under the n-type electrode 509. A higher electrical power to light conversion efficiency is thus obtained.

FIG. 6 shows a finite-element-method (FEM) simulated current density distribution curve of a vertical LED with current blocking. As shown, the current block on the p-type electrode side effectively pushes the current flow away from the n-type electrode so that light is generated in the area without obstruction of the n-type electrode. In addition, the current density distribution becomes more uniform and the ratio of current density maximum/minimum is reduced to about 4.5 in comparison with 6 in the case of FIG. 3 that shows a curve without current-blocking.

Example embodiments in accordance with aspects of the present invention have now been described in accordance with the above advantages. It will be appreciated that these examples are merely illustrative of aspects of the present invention. Many variations and modifications will be apparent to those skilled in the art.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

What is claimed is:

1. A light emitting diode, comprising:
an epitaxial layer structure;
a first electrode formed on the epitaxial layer structure, the first electrode having a pattern; and
a second electrode formed on the epitaxial layer structure, the second electrode having a portion aligned with the pattern of the first electrode,
wherein the portion of the second electrode forms a non-ohmic contact with the epitaxial layer structure.

2. The light emitting diode of claim 1, wherein the epitaxial layer structure comprises first and second epitaxial layers, wherein the first epitaxial layer is between the first electrode and the second epitaxial layer, and the second epitaxial layer is between the second electrode and the first epitaxial layer.

3. The light emitting diode of claim 2, further comprising an active region between the first and second epitaxial layers.

4. The light emitting diode of claim 2, wherein the non-ohmic contact portion exists between the second electrode and the second epitaxial layer.

5. The light emitting diode of claim 2, wherein the non-ohmic contact portion has a Schottky contact with the second epitaxial layer.

6. The light emitting diode of claim 2, wherein the non-ohmic contact portion is formed via a plasma treatment on the second epitaxial layer.

7. The light emitting diode of claim 2, wherein the non-ohmic contact portion is formed by photo-resisting the second epitaxial layer and plasma-treating the photoresisted epitaxial layer so that the non-ohmic contact portion is formed between the second electrode and the second epitaxial layer where the second epitaxial layer is not covered by a photo-resist.

8. The light emitting-diode of claim 7, wherein the plasma treatment uses a gas including O₂, N₂, H₂, Ar, He, Ne, Kr, Xe, or any combination thereof.

9. The light emitting diode of claim 7, wherein the non-ohmic contact portion includes a metal selected from Ag, Pt, Ni, Cr, Ti, Al, Cu, Pd, W, Ru, Rh, Mo, and their alloys.

10. The light emitting diode of claim 7, wherein the plasma treatment compensates a doping concentration near a surface of the second epitaxial layer.

11. The light emitting diode of claim 7, wherein the plasma treatment converts a doping of the second eptiaxial layer at areas treated by the plasma treatment into an opposite doping.

12. The emitting diode of claim 1, wherein a width of the pattern of the non-ohmic contact portion is equal to or greater than a width of the pattern of the first electrode.

13. The light emitting diode of claim 1, wherein the second electrode comprises a metal selected from Ag, Pt, Ni, Cr, Ti, Al, Cu, Pd, W, Ru, Rh, Mo, and their alloys.

14. The light emitting diode of claim 1, wherein the second electrode layer comprises first and second materials, wherein the second material forms the non-ohmic contact portion with the epitaxial layer structure.

15. The light emitting diode of claim 14, wherein the first material includes a metal selected from Ag, Pt, Ni, Cr, Ti, Al, Cu, Pd, W, Ru, Rh, Mo, and their alloys.

16. The light emitting diode of claim 14, wherein the first material is formed partially on the epitaxial layer structure and areas on the epitaxial layer structure without the first material forms a pattern aligned with that pattern of the first electrode, wherein the second material is formed on the first material.

17. The light emitting diode of claim 1, wherein the second electrode is attached to a substrate.

18. The light emitting diode of claim 17, wherein the substrate is selected from a group consisting of a metal, a semiconductor material, and a ceramic.

19. The light emitting diode of claim 18, wherein the metal includes one selected from Cu, Mo, W, and Al, the semiconductor includes one selected from Si, GaAs, GaP, InP, and Ge, and the ceramic includes one selected from Al₂O₃ and AlN.

20. A method for manufacturing a light emitting diode, comprising:
forming an epitaxial layer structure;
forming a first electrode, the first electrode having a first pattern on the epitaxial layer structure; and
forming a second electrode on the epitaxial layer structure,
wherein the second electrode is formed with a portion aligned with the pattern of the first electrode, the portion of the second electrode forming a non-ohmic contact with the epitaxial layer structure.

21. The method of claim 20, wherein the epitaxial layer structure comprises a first epitaxial layer and a second epitaxial layer, wherein the first electrode is formed on the first epitaxial layer and the second electrode is formed on the second epitaxial layer.

22. The method of claim 21, further comprising forming an active region between the first and second epitaxial layers.

23. The method of claim 21, wherein the non-ohmic contact portion is formed via a plasma treatment on the second epitaxial layer.

24. The method of claim 21, wherein the non-ohmic contact portion is formed by photo-resisting the second epitaxial layer and plasma-treating the photoresisted epitaxial layer so that the non-ohmic contact portion is formed between the second electrode and the second epitaxial layer where the second epitaxial layer is not covered by a photo-resist.

25. The method of claim 24, wherein the plasma treatment uses gases including O₂, N₂, H₂, Ar, He, Ne, Kr, Xe, or their mixture.

26. The method of claim 24, wherein the plasma treatment compensates a doping concentration near a surface of the second epitaxial layer that are not covered by a photo-resist layer.

27. The method of claim 24, wherein the plasma treatment converts a doping of the second epitaxial layer at areas treated by the plasma treatment into an opposite doping.

28. The method of claim 20, wherein a width of the pattern of the non-ohmic contact portion is equal to or greater than a width of the pattern of the first electrode.

29. The method of claim 20, wherein the second electrode is formed by depositing a metal selected from Ag, Pt, Ni, Cr, Ti, Al, Cu, Pd, W, Ru, Rh, Mo, and their alloys.

30. The method of claim 21, wherein the forming of the epitaxial layer structure comprises forming the first epitaxial layer on a substrate, and removing the substrate, and wherein the first electrode is formed on a surface of the first epitaxial layer that was attached to the substrate.

31. The method of claim 30, wherein the substrate is sapphire (Al₂O₃) or silicon carbide (SiC).

32. The method of claim 20, further comprising attaching the second electrode to a substrate.

33. The method of claim 32, wherein the substrate is selected from a group consisting of a metal, a semiconductor material, and a ceramic.

34. The method of claim 33, wherein the metal includes one selected from Cu, Mo, W, and Al, the semiconductor material includes one selected from Si, GaAs, GaP, InP, and Ge, and the ceramic includes one selected from Al₂O₃ and AlN.

35. The method of claim 20, wherein forming of the second electrode comprises patterning a first material with a pattern opposite parity to the pattern of the first electrode, and arranging a second material with the first material, the non-ohmic contact portion being between the second material and the epitaxial layer structure.

36. The method of claim 35, wherein the first material is formed on the epitaxial layer structure, and is etched to form a pattern that are aligned with the pattern of the first electrode, wherein the second material is deposited on the first material after the etching process and is in touch with the epitaxial layer structure.

37. The method of claim 35, wherein the non-ohmic contact portion is formed by depositing a metal selected from Ag, Pt, Ni, Cr, Ti, Al, Cu, Pd, W, Ru, Rh, Mo, and their alloys.
